(19) United States
(12) Patent Application Publication
(10) Pub. No.: US 2024/0222117 A1
(43) Pub. Date: Jul. 4, 2024

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventor: Yuki YOSHIMOTO, Toyama (JP)

(73) Assignee: KOKUSAI ELECTRIC CORPORATION, Tokyo (JP)

(21) Appl. No.: 18/377,159

(22) Filed: Oct. 5, 2023

(30) Foreign Application Priority Data
Dec. 28, 2022 (JP) 2022-212435

(51) Int. Cl. H01L 21/02; C23C 16/06; C23C 16/46; C23C 16/52

(52) U.S. Cl. CPC H01L 21/02658; C23C 16/06; C23C 16/46; C23C 16/52; H01L 21/02532

(57) ABSTRACT

There is provided a technique that includes (a) forming a layer including a surface terminated with an element X on a surface of a substrate by supplying an element X-containing gas to the substrate which is set to have a first temperature, (b) changing a surface termination with the element X on the surface of the layer to a surface termination with an element Y by supplying an element Y-containing gas to the substrate which is set to have a second temperature, (c) desorbing the element Y constituting the surface termination with the element Y on the surface of the layer by setting the substrate to have a third temperature, and (d) forming a film on the layer from which the element Y is desorbed, by supplying a film-forming gas to the substrate which is set to have a fourth temperature.

### CROSS-REFERENCE TO RELATED APPLICATION

This application is based upon and claims the benefit of priority from Japanese Patent Application No. 2022-212435, filed on Dec. 28, 2022, the entire contents of which are incorporated herein by reference.

### TECHNICAL FIELD

The present disclosure relates to a method of processing substrate, a method of manufacturing a semiconductor device, a substrate processing apparatus, and a recording medium.

### BACKGROUND

In the related art, as a process of manufacturing a semiconductor device, a process of forming a film on a substrate is sometimes performed.

With miniaturization of semiconductor devices, improvements in properties of films formed on substrates are strongly demanded.

### SUMMARY

Some embodiments of the present disclosure provide a technique capable of improving the properties of a film formed on a substrate.

According to one embodiment of the present disclosure, there is provided a technique that includes: (a) forming a layer including a surface terminated with an element X on a surface of a substrate by supplying an element X-containing gas to the substrate which is set to have a first temperature, (b) changing a surface termination with the element X on the surface of the layer to a surface termination with an element Y by supplying an element Y-containing gas to the substrate which is set to have a second temperature, (c) desorbing the element Y constituting the surface termination with the element Y on the surface of the layer by setting the substrate to have a third temperature, and (d) forming a film on the layer from which the element Y is desorbed, by supplying a film-forming gas to the substrate which is set to have a fourth temperature.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in one embodiment of the present disclosure, in which the portion of the process furnace is illustrated in a vertical sectional view.

FIG. 2 is a schematic configuration diagram of the vertical process furnace of the substrate processing apparatus suitably used in one embodiment of the present disclosure, in which the portion of the process furnace is illustrated in a sectional view taken along line A-A in FIG. 1.

FIG. 3 is a schematic configuration diagram of a controller of the substrate processing apparatus suitably used in one embodiment of the present disclosure, in which a control system of the controller is illustrated in a block diagram.

FIG. 4 is a diagram showing a processing sequence in one embodiment of the present disclosure.

FIG. 5A is a TEM image showing a surface portion of a wafer in evaluation sample 2 of Example 2, and FIG. 5B is a TEM image showing a surface portion of a wafer in evaluation sample 4 of Comparative Example 1.

FIG. 6 is a graph showing evaluation results in Examples 1 to 3 and Comparative Example 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### One Embodiment of the Present Disclosure

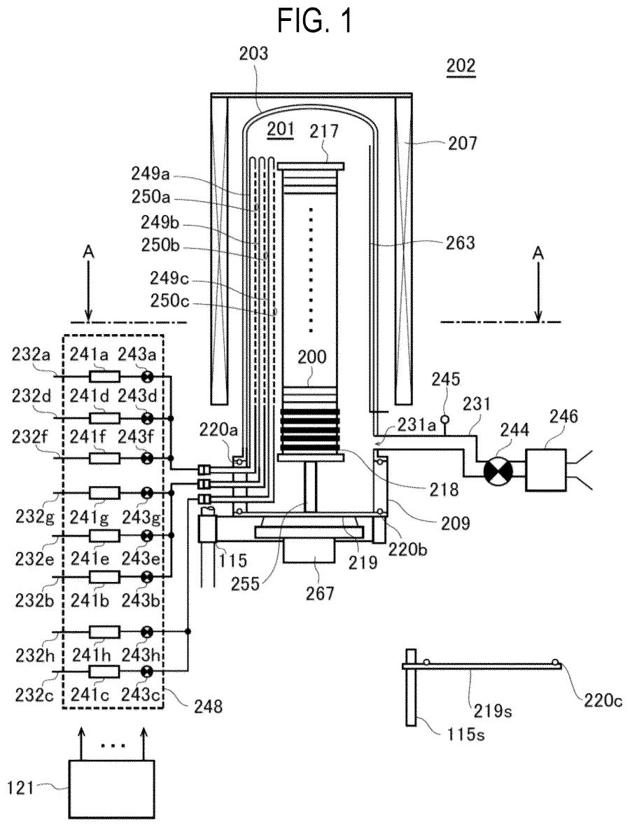

Hereinafter, one embodiment of the present disclosure will be described mainly with reference to FIGS. 1 to 4. The drawings used in the following description are all schematic, and the dimensional relationship of each element, the ratio of each element, and the like shown in the drawings do not necessarily match the actual ones. Moreover, the dimensional relationship of each element, the ratio of each element, and the like do not necessarily match between a plurality of drawings.

### (1) Configuration of Substrate Processing Apparatus (Substrate Processing System)

As shown in FIG. 1, a process furnace 202 includes a heater 207 as a temperature regulator (heating part). The heater 207 has a cylindrical shape and is vertically installed by being supported by a holding plate. The heater 207 functions as an energy application part for applying energy to a gas and also functions as an activation mechanism (excitation part) if it activates (excites) a gas with heat.

Inside the heater 207, a reaction tube 203 is arranged concentrically with the heater 207. The reaction tube 203 is made of a heat-resistant material such as, for example, quartz (SiO₂) or silicon carbide (SiC) and is formed in a cylindrical shape with an upper end thereof closed and a lower end thereof opened. Below the reaction tube 203, a manifold 209 is arranged concentrically with the reaction tube 203. The manifold 209 is made of a metallic material such as stainless steel (SUS) or the like and is formed in a cylindrical shape with upper and lower ends thereof opened. The upper end of the manifold 209 is engaged with the lower end of the reaction tube 203 and is configured to support the reaction tube 203. An O-ring 220a as a seal is installed between the manifold 209 and the reaction tube 203. The reaction tube 203 is installed vertically like the heater 207. A process container (reaction container) mainly includes the reaction tube 203 and the manifold 209. A process chamber 201 is formed in the hollow portion of the process container. The process chamber 201 is configured to accommodate wafers 200 as substrates. The wafers 200 are processed in the process chamber 201.

Nozzles 249a to 249c as first to third suppliers are installed in the process chamber 201 to penetrate a side wall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The respective nozzles 249a to 249c are different nozzles, and the respective nozzles 249a and 249c are installed adjacent to the nozzle 249b.

At the gas supply pipes 232a to 232c, mass flow controllers (MFCs) 241a to 241c, which are flow rate controllers (flow control parts), and valves 243a to 243c, which are on-off valves, are respectively installed in this order from an upstream side of a gas flow. Gas supply pipes 232d and 232f are connected to the gas supply pipe 232a on a downstream side of the valve 243a. Gas supply pipes 232e and 232g are connected to the gas supply pipe 232b on the downstream side of the valve 243b. A gas supply pipe 232h is connected to the gas supply pipe 232c on a downstream side of the valve 243c. At the gas supply pipes 232d to 232h, MFCs 241d to 241h and valves 243d to 243h are respectively installed in this order from an upstream side of a gas flow. The gas supply pipes 232a to 232h are made of, for example, a metallic material such as stainless steel or the like.

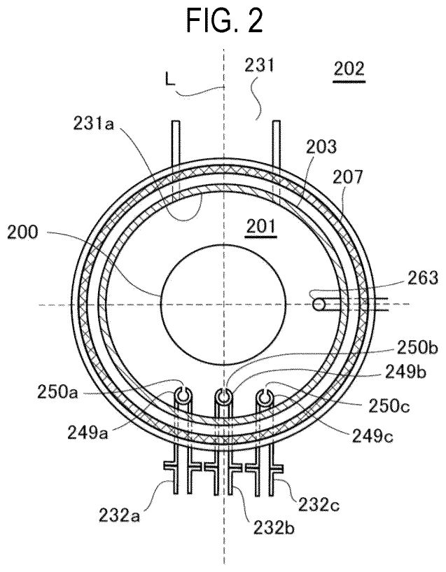

As shown in FIG. 2, the nozzles 249a to 249c are respectively installed in a space having an annular shape in a plan view between an inner wall of the reaction tube 203 and the wafers 200 to extend upward in an arrangement direction of the wafers 200 from a lower portion to an upper portion of the inner wall of the reaction tube 203. In other words, the nozzles 249a to 249c are respectively installed at a region horizontally surrounding a wafer arrangement region, at which the wafers 200 are arranged, at a lateral side of the wafer arrangement region to extend along the wafer arrangement region. In the plan view, the nozzle 249b is arranged to face the below-described exhaust port 231a on a straight line across centers of the wafers 200 loaded into the process chamber 201. The nozzles 249a and 249c are arranged to sandwich a straight line L passing through the nozzle 249b and a center of the exhaust port 231a from both sides along the inner wall of the reaction tube 203 (outer peripheral portions of the wafers 200). The straight line L is also a straight line passing through the nozzle 249b and the centers of the wafers 200. That is, it can be said that the nozzle 249c is installed on opposite side to the nozzle 249a with the straight line L interposed therebetween. The nozzles 249a and 249c are arranged line-symmetrically with the straight line L as an axis of symmetry. Gas supply holes 250a to 250c which supply gases are formed at the side surfaces of the nozzles 249a to 249c, respectively. The gas supply holes 250a to 250c are respectively opened to face the exhaust port 231a in the plan view and can supply gases toward the wafers 200. The gas supply holes 250a to 250c are formed from a lower portion to an upper portion of the reaction tube 203.

An element X-containing gas is supplied from the gas supply pipe 232a into the process chamber 201 via the MFC 241a, the valve 243a, and the nozzle 249a.

A silicon (Si)-containing gas is supplied from the gas supply pipe 232b into the process chamber 201 via the MFC 241b, the valve 243b, and the nozzle 249b.

A film-forming gas is supplied from the gas supply pipe 232c into the process chamber 201 via the MFC 241c, the valve 243c, and the nozzle 249c.

An element Y-containing gas is supplied from the gas supply pipe 232d into the process chamber 201 via the MFC 241d, the valve 243d, the gas supply pipe 232a, and the nozzle 249a.

A dopant gas is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like.

An element X-containing gas supply system mainly includes the gas supply pipe 232a, the MFC 241a, and the valve 243a. A Si-containing gas supply system mainly includes the gas supply pipe 232b, the MFC 241b, and the valve 243b. A film-forming gas supply system mainly includes the gas supply pipe 232c, the MFC 241c, and the valve 243c. An element Y-containing gas supply system mainly includes the gas supply pipe 232d, the MFC 241d, and the valve 243d. A dopant gas supply system mainly includes the gas supply pipe 232e, the MFC 241e, and the valve 243e. An inert gas supply system mainly includes the gas supply pipes 232f to 232h, the MFCs 241f to 241h, and the valves 243f to 243h.

Any or all of the various supply systems described above may be configured as an integrated supply system 248 in which the valves 243a to 243h, the MFCs 241a to 241h, and the like are integrated. The integrated supply system 248 is connected to each of the gas supply pipes 232a to 232h, and is configured such that an operation of supplying various substances (various gases) into the gas supply pipes 232a to 232h, i.e., an opening/closing operation of the valves 243a to 243h, a flow rate adjustment operation by the MFCs 241a to 241h, and the like, are controlled by a controller 121 described below. The integrated supply system 248 is configured as an integral or divided integrated unit, and is configured such that the integrated supply system 248 can be attached to and detached from the gas supply pipes 232a to 232h, and the like on an integrated unit basis, and the maintenance, replacement, expansion, and the like of the integrated supply system 248 can be performed on an integrated unit basis.

An exhaust port 231a which exhausts the atmosphere in the process chamber 201 is installed at a lower portion of a side wall of the reaction tube 203. As shown in FIG. 2, the exhaust port 231a is installed at a position facing the nozzles 249a to 249c (gas supply holes 250a to 250c) with the wafers 200 interposed therebetween in the plan view. The exhaust port 231a may be installed to extend from the lower portion to the upper portion of the side wall of the reaction tube 203, i.e., along the wafer arrangement region. An exhaust pipe 231 is connected to the exhaust port 231a. A vacuum pump 246 as an evacuation device is connected to the exhaust pipe 231 via a pressure sensor 245 as a pressure detector (pressure detection part) which detects a pressure inside the process chamber 201 and an APC (Auto Pressure Controller) valve 244 as a pressure regulator (pressure regulation part). The APC valve 244 is configured to perform or stop vacuum evacuation of an interior of the process chamber 201 by setting a valve to be opened and closed in a state in which the vacuum pump 246 is operated, and also configured to regulate the pressure inside the process chamber 201 by adjusting a valve opening degree based on pressure information detected by the pressure sensor 245 in a state in which the vacuum pump 246 is operated. An exhaust system mainly includes the exhaust pipe 231, the APC valve 244 and the pressure sensor 245. The vacuum pump 246 may be included in the exhaust system.

A seal cap 219 as a furnace opening lid capable of airtightly closing a lower end opening of the manifold 209 is installed below the manifold 209. The seal cap 219 is made of a metallic material such as, for example, stainless steel or the like, and is formed in a disc shape. An O-ring 220b as a seal which abuts against a lower end of the manifold 209 is installed at an upper surface of the seal cap 219. A rotator 267 which rotates a boat 217 described below is installed below the seal cap 219. A rotating shaft 255 of the rotator 267 is connected to the boat 217 through the seal cap 219. The rotator 267 is configured to rotate the wafers 200 by rotating the boat 217. The seal cap 219 is configured to be raised and lowered in the vertical direction by a boat elevator 115 as an elevating mechanism installed outside the reaction tube 203. The boat elevator 115 is configured as a transport device (transport mechanism) that loads and unloads (transports) the wafers 200 into and out of the process chamber 201 by raising and lowering the seal cap 219.

Below the manifold 209, a shutter 219s is installed as a furnace opening lid capable of airtightly closing the lower end opening of the manifold 209 in a state in which the seal cap 219 is lowered and the boat 217 is unloaded from the process chamber 201. The shutter 219s is made of a metallic material such as stainless steel or the like and is formed in a disk shape. An O-ring 220c as a seal which abuts against the lower end of the manifold 209 is installed at an upper surface of the shutter 219s. The opening/closing operation (an elevating operation, an rotating operation, and the like) of the shutter 219s are controlled by a shutter opening/closing mechanism 115s.

The boat 217 as a substrate support tool is configured to support a plurality of wafers 200, for example, 25 to 200 wafers 200 in a horizontal posture and in multiple stages while vertically arranging the wafers 200 with the centers thereof aligned with each other, i.e., to arrange the wafers 200 at intervals. The boat 217 is made of a heat-resistant material such as, for example, quartz or SiC. Heat insulating plates 218 made of a heat-resistant material such as, for example, quartz or SiC, are supported in multiple stages at the bottom of the boat 217.

Inside the reaction tube 203, a temperature sensor 263 as a temperature detector is installed. By adjusting a state of supplying electric power to the heater 207 based on temperature information detected by the temperature sensor 263, the temperature inside the process chamber 201 becomes a desired temperature distribution. The temperature sensor 263 is installed along the inner wall of the reaction tube 203.

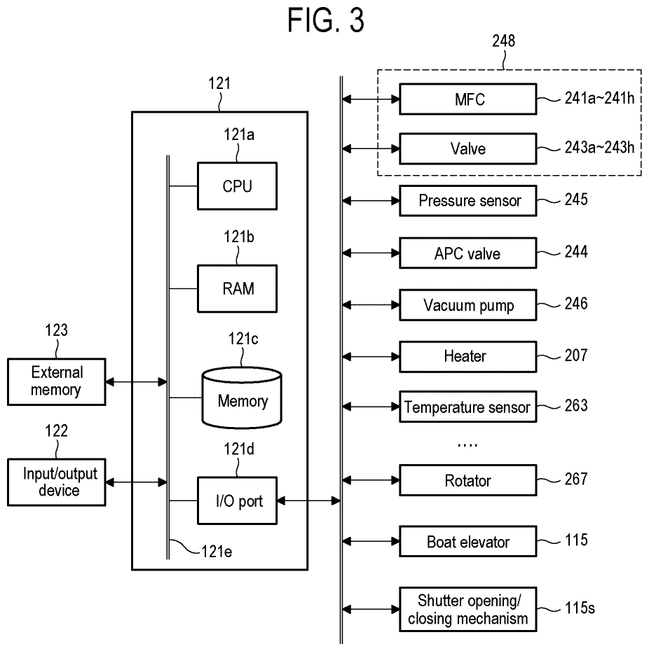

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to exchange data with the CPU 121a via an internal bus 121e. An input/output device 122 including, for example, a touch panel or the like is connected to the controller 121. In addition, an external memory 123 can be connected to the controller 121.

The memory 121c includes, for example, a flash memory, a HDD (Hard Disk Drive), a SSD (Solid State Drive), or the like. In the memory 121c, a control program which controls an operation of the substrate processing apparatus, a process recipe in which procedures, conditions, and the like of substrate processing described below, are written, and the like are readably recorded and stored. The process recipe is a combination that causes, by the controller 121, the substrate processing apparatus (substrate processing system) to execute the respective procedures in a substrate processing process described below to obtain a predetermined result, and functions as a program. Hereinafter, the process recipe, the control program and the like are collectively and simply referred to as a program. Further, the process recipe is also simply referred to as a recipe. When the term “program” is used herein, it may mean a case of including only the recipe, a case of including only the control program, or a case of including both the recipe and the control program. The RAM 121b is configured as a memory area (work area) in which programs, data and the like read by the CPU 121a are temporarily held.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, and the like.

The CPU 121a is configured to read and execute the control program from the memory 121c and to read the recipe from the memory 121c in response to an input of an operation command from the input/output device 122 or the like. The CPU 121a is configured to, according to the contents of the recipe thus read, control the flow rate adjustment operation for various substances (various gases) by the MFCs 241a to 241h, the opening/closing operation of the valves 243a to 243h, the opening/closing operation of the APC valve 244, the pressure regulation operation by the APC valve 244 based on the pressure sensor 245, the start and stop of the vacuum pump 246, the temperature regulation operation of the heater 207 based on the temperature sensor 263, rotation and rotation speed adjustment operation of the boat 217 by the rotator 267, the raising and lowering operation of the boat 217 by the boat elevator 115, the opening/closing operation of the shutter 219s by the shutter opening/closing mechanism 115s, and the like.

The controller 121 may be configured by installing, in the computer, the above-described program recorded and stored in an external memory 123. The external memory 123 includes, for example, a magnetic disk such as a HDD or the like, an optical disk such as a CD or the like, a magneto-optical disk such as an MO or the like, a semiconductor memory such as a USB memory, a SSD, or the like, and so forth. The memory 121c and the external memory 123 are configured as a non-transitory computer readable recording medium. Hereinafter, the memory 121c and the external memory 123 are collectively and simply referred to as a recording medium. As used herein, the term “recording medium” may include only the memory 121c, only the external memory 123, or both. The provision of the program to the computer may be performed by using a communication means such as the Internet or a dedicated line without using the external memory 123.

### (2) Substrate Processing Process

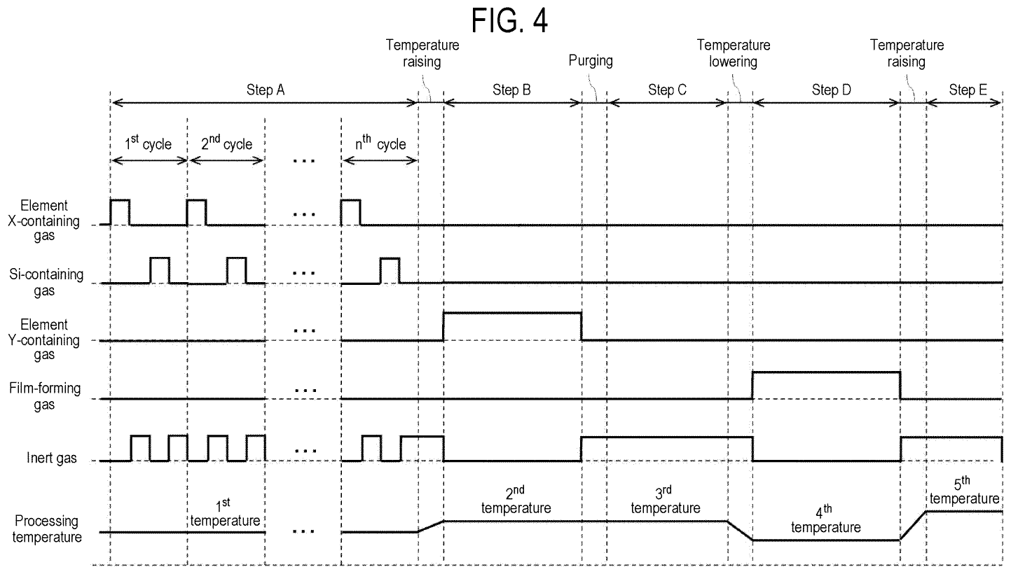

A method of processing a substrate as one process of a process (method) of manufacturing a semiconductor device, by using the substrate processing apparatus described above, i.e., an example of a processing sequence for forming a layer on a surface of a wafer 200 as a substrate and forming a film on the layer, will be described mainly with reference to FIG. 4. In the following description, an operation of each component of the substrate processing apparatus is controlled by the controller 121. The layer formed on the surface of the wafer 200 is thinner than the film formed on this layer and serves as a nucleus (seed) when forming (growing) the film on this layer. Thus, this layer is also called a seed layer.

A processing sequence according to the present embodiment includes:
(a) step A of forming a seed layer including a surface terminated with an element X on a surface of a wafer 200 by supplying an element X-containing gas to the wafer 200 which is set to have a first temperature,
(b) step B of changing a termination (i.e., a surface termination) with the element X on the surface of the seed layer to a termination (i.e., a surface termination) with an element Y by supplying an element Y-containing gas to the wafer 200 which is set to have a second temperature,
(c) step C of desorbing the element Y constituting the termination with the element Y on the surface of the seed layer by setting the substrate to have a third temperature, and
(d) step D of forming a film on the seed layer from which the element Y is desorbed, by supplying a film-forming gas to the wafer 200 which is set to have a fourth temperature. The seed layer may be simply referred to as a layer.

In the following example, there will be described a case where, as shown in FIG. 4, in step A, the element X-containing gas and a Si-containing gas are alternately supplied to the wafer 200. In the following example, in step A, the seed layer is formed on the surface of the wafer 200 by performing a cycle including step A1 of supplying the element X-containing gas to the wafer 200 and step A2 of supplying the Si-containing gas to the wafer 200 a predetermined number of times (n times where n is an integer of 1 or more).

Further, in the following example, a case where, in step D, a germanium (Ge)-containing gas is supplied as the film-forming gas to the wafer 200 will be described. In step D, the Ge-containing gas and the dopant gas may be simultaneously supplied to the wafer 200.

In this specification, the processing sequence described above may also be denoted as follows for the sake of convenience. The same notation is also used in the following description of a modification, another embodiment, and the like.
[Element X-containing gas→Si-containing gas]×n→element Y-containing gas→inert gas→film-forming gas

Further, in the following example, as shown in FIG. 4, step E of heat-treating the wafer 200 is further performed after step D is performed. Step E may be omitted. This point also applies to modifications and other embodiments described below.
[Element X-containing gas→Si-containing gas]×n→element Y-containing gas→inert gas→film-forming gas→heat treatment

In the following example, a case where, as shown in FIG. 4, the second temperature is set to be higher than the first temperature, the third temperature is set to be higher than the first temperature, and the fourth temperature is set to be lower than the first temperature will be described. Further, in the following example, a case where, as shown in FIG. 4, the second temperature and the third temperature are the same will be described.

The term “wafer” used herein may refer to a wafer itself or a stacked body of a wafer and a predetermined layer or film formed on the surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

As used herein, the term “layer” includes at least one selected from the group of a continuous layer and a discontinuous layer. For example, the seed layer may include a continuous layer, a discontinuous layer, or both of them.

### (Wafer Charging and Boat Loading)

After a plurality of wafers 200 is charged to the boat 217 (wafer charging), the shutter 219s is moved by the shutter opening/closing mechanism 115s to open the lower end opening of the manifold 209 (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafer 200 is prepared in the process chamber 201.

### (Pressure Regulation and Temperature Regulation)

After the boat loading is completed, inside of the process chamber 201, i.e., a space where the wafer 200 exists, is evacuated into vacuum (evacuated into a reduced pressure) by the vacuum pump 246 so that the pressure inside the process chamber 201 becomes a desired pressure (degree of vacuum). At this time, the pressure inside the process chamber 201 is measured by the pressure sensor 245, and the APC valve 244 is subjected to feedback control based on the measured pressure information. Further, the wafer 200 in the process chamber 201 is heated by the heater 207 so that the wafer 200 has a desired processing temperature. At this time, the state of supplying electric power to the heater 207 is feedback-controlled based on the temperature information detected by the temperature sensor 263 so that the inside of the process chamber 201 has a desired temperature distribution. Moreover, rotation of the wafer 200 by the rotator 267 is started. The evacuation of the process chamber 201 and the heating and the rotation of the wafer 200 are continuously performed at least until the process to the wafer 200 is completed.

### (Step A)

Thereafter, the element X-containing gas is supplied to the wafer 200 which is set to have the first temperature. Specifically, in this step, the following steps A1 and A2 are sequentially executed. As a result, the seed layer including the surface terminated with the element X is formed on the surface of the wafer 200.

### [Step A1]

In this step, the element X-containing gas is supplied to the wafer 200 which is set to have the first temperature.

Specifically, the valve 243a is opened to allow the element X-containing gas to flow into the gas supply pipe 232a. The flow rate of the element X-containing gas is adjusted by the MFC 241a. The element X-containing gas is supplied into the process chamber 201 through the nozzle 249a and is exhausted from the exhaust port 231a. At this time, the element X-containing gas is supplied to the wafer 200 from the lateral side of the wafer 200 (element X-containing gas supply). At this time, the valves 243f to 243h may be opened to supply the inert gas into the process chamber 201 through the nozzles 249a to 249c, respectively.

A processing condition when supplying the element X-containing gas in this step is exemplified as follows.
Processing temperature (first temperature): 350 to 440 degrees C.
Processing pressure: 100 to 1000 Pa
Element X-containing gas supply flow rate: 0.01 to 1 slm
Element X-containing gas supply time: 0.5 to 10 minutes
Inert gas supply flow rate (for each gas supply pipe): 0.01 to 10 slm

Further, in this specification, an expression of a numerical range such as “350 to 440 degrees C.” means that a lower limit and an upper limit are included in the range. Therefore, for example, “350 to 440 degrees C.” means “350 degrees C. or higher and 440 degrees C. or lower.” The same applies to other numerical ranges. Further, the processing temperature in this specification means the temperature of the wafer 200 or the temperature inside the process chamber 201, and the processing pressure means the pressure inside the process chamber 201. Moreover, a processing time means the time during which the process is continued. In addition, when 0 slm is included in the supply flow rate, 0 slm means a case where the gas is not supplied. These also hold true in the following description.

After the supply of the element X-containing gas to the wafer 200 is completed, the valve 243a is closed to stop the supply of the element X-containing gas into the process chamber 201. Then, the process chamber 201 is evacuated to remove gaseous substances remaining in the process chamber 201 from the process chamber 201. At this time, the valves 243f to 243h are opened to supply the inert gas into the process chamber 201 through the nozzles 249a to 249c. The inert gas supplied from the nozzles 249a to 249c acts as a purge gas, thereby purging the inside of the process chamber 201 (purging).

A processing condition when performing the purging in this step is exemplified as follows.
Processing pressure: 1 to 30 Pa
Processing time: 1 to 120 seconds, preferably 1 to 60 seconds
Inert gas supply flow rate (in each gas supply pipe): 0.5 to 20 slm

Further, the processing temperature at the time of purging may be the same as the processing temperature (first temperature) at the time of supplying the element X-containing gas.

As the element X-containing gas, for example, a gas containing Si and halogen as an element X, i.e., a halosilane-based gas, may be used. Halogen as the element X includes chlorine (Cl), fluorine (F), bromine (Br), iodine (I), or the like. As the halosilane-based gas, for example, a silane-based gas containing a Si—Cl bond, a Si—F bond, a Si—Br bond or a Si—I bond, i.e., a chlorosilane-based gas, a fluorosilane-based gas, a bromosilane-based gas, or an iodosilane-based gas may be used. Among them, it may use, for example, the chlorosilane-based gas as the halosilane-based gas. That is, the element X in the element X-containing gas may include halogen, and may include Cl.

Examples of the element X-containing gas include a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane (Si₂Cl₆) gas, an octachlorotrisilane (Si₃Cl₈) gas, or the like. As the element X-containing gas, one or more of these gases may be used.

As the inert gas, a nitrogen (N₂) gas, or a rare gas such as an argon (Ar) gas, a helium (He) gas, a neon (Ne) gas, or a xenon (Xe) gas may be used. One or more of these gases may be used as the inert gas. This point also applies to each step described below.

### [Step A2]

After step A1 is completed, a Si-containing gas is supplied to the wafer 200 which is set to have the first temperature.

Specifically, the valve 243b is opened to allow the Si-containing gas to flow into the gas supply pipe 232b. The flow rate of the Si-containing gas is adjusted by the MFC 241b. The Si-containing gas is supplied into the process chamber 201 through the nozzle 249b and is exhausted from the exhaust port 231a. At this time, the Si-containing gas is supplied to the wafer 200 from the lateral side of the wafer 200 (Si-containing gas supply). At this time, the valves 243f to 243h may be opened to supply the inert gas into the process chamber 201 through the nozzles 249a to 249c, respectively.

A processing condition when supplying the Si-containing gas in this step is exemplified as follows.
Processing temperature (first temperature): 350 to 440 degrees C.
Processing pressure: 100 to 1000 Pa
Si-containing gas supply flow rate: 0.01 to 1 slm
Si-containing gas supply time: 0.5 to 10 minutes
Inert gas supply flow rate (for each gas supply pipe): 0.01 to 10 slm

After the supply of the Si-containing gas to the wafer 200 is completed, the valve 243b is closed to stop the supply of the Si-containing gas into the process chamber 201. Then, the gaseous substances remaining in the process chamber 201 are removed from the process chamber 201 by the same processing procedure and processing conditions as those of the purging in step A1 (purging). In addition, the processing temperature at the time of purging may be the same as the processing temperature (first temperature) at the time of supplying the Si-containing gas.

As the Si-containing gas, for example, a gas containing Si and hydrogen (H), i.e., a silicon hydride-based gas, a gas containing Si and an amino group, i.e., an aminosilane-based gas, or the like may be used. As the aminosilane-based gas, for example, an aminosilane-based gas containing a Si—N bond in which an amino group is directly bonded to Si may be used.

As the Si-containing gas, for example, a monosilane (SiH₄) gas, a disilane (Si₂H₆) gas, a trisilane (Si₃H₈) gas, a tetrasilane (Si₄H₁₀) gas, a pentasilane (Si₅H₁₂) gas, a hexasilane (Si₆H₁₄) gas, or the like. Further, examples of the Si-containing gas include a tetrakis(dimethylamino)silane (Si[N(CH₃)_{2]4}) gas, a tris(dimethylamino)silane (Si[N(CH₃)_{2]3}H) gas, a bis(diethylamino)silane (Si[N(C₂H₅)_{2]2}H₂) gas, a bis(tertiary butyl)aminosilane (Si[NH(C₄H₉)]₂H₂) gas, a (diisobutylamino)silane ((C₄H₉)₂NSiH₃) gas, a (diisopropylamino)silane ((C₃H₇)₂NSiH₃) gas, or the like. One or more of these gases may be used as the Si-containing gas.

### [Performing a Predetermined Number of Times]

A cycle including steps A1 and A2, i.e., a cycle in which steps A1 and A2 are performed non-simultaneously (alternately) as shown in FIG. 4, is performed the predetermined number of times (n times where n is an integer of 1 or more). Thus, the seed layer including the surface terminated with the element X can be formed on the surface of the wafer 200. The above cycle may be repeated multiple times until the thickness of the seed layer, including the surface terminated with element X, reaches a desired thickness.

For example, in this step, a seed layer including a surface having a Si—X termination can be formed on the surface of the wafer 200 by using the element X-containing gas described above. As described above, the element X may include halogen, and may include Cl. Therefore, in this step, it may form a seed layer including a surface having a Si-halogen termination on the surface of the wafer 200, and may form a seed layer including a surface having a Si—Cl termination.

### (Temperature Raising)

After the seed layer including the surface terminated with the element X is formed on the surface of the wafer 200, an output of the heater 207 is adjusted to raise the processing temperature from the first temperature to the second temperature which is set to be higher than the first temperature as shown in FIG. 4. At this time, the inside of the process chamber 201 is purged according to the same processing procedure and processing conditions as those of the purging in step A1. The purging may be continued until the temperature of the wafer 200 reaches the second temperature and stabilizes.

### (Step B)

After the temperature of the wafer 200 reaches the second temperature and stabilizes, an element Y-containing gas is supplied to the wafer 200 which is set to have the second temperature.

Specifically, the valve 243d is opened to allow the element Y-containing gas to flow into the gas supply pipe 232d. The flow rate of the element Y-containing gas is adjusted by the MFC 241d. The element Y-containing gas is supplied into the process chamber 201 through the nozzle 249a and is exhausted from the exhaust port 231a. At this time, the element Y-containing gas is supplied to the wafer 200 from the lateral side of the wafer 200 (element Y-containing gas supply). At this time, the valves 243f to 243h may be opened to supply the inert gas into the process chamber 201 through the nozzles 249a to 249c.

In this step, as shown in FIG. 4, the second temperature is set to be higher than the first temperature. Therefore, in this step, the output of the heater 207 is adjusted to maintain the processing temperature (second temperature) higher than the processing temperature (first temperature) in step A (steps A1 and A2).

By supplying the element Y-containing gas to the wafer 200 under the processing conditions described below, a substitution reaction can be caused to substitute (change) the element X with the element Y at the surface of the seed layer, and the termination with the element X on the surface of the seed layer can be changed to a termination with the element Y. In particular, by setting the second temperature to be higher than the first temperature, it is possible to increase the conversion rate of the termination with the element X on the surface of the seed layer to the termination with the element Y, and to prevent the termination with element X from remaining on the surface of the seed layer. Thus, in this step, it is possible to create a state in which the seed layer including the surface terminated with the element Y is formed on the surface of the wafer 200.

A processing condition when supplying the element Y-containing gas in this step is exemplified as follows.
Processing temperature (second temperature): 400 to 520 degrees C., preferably 450 to 500 degrees C.
Processing pressure: 500 to 101325 Pa, preferably 800 to 10133 Pa
Processing time: 0.5 to 2 hours, preferably 0.5 to 1 hour
Element Y-containing gas supply flow rate: 1 to 5 slm, preferably 2 to 3 slm
Inert gas supply flow rate (for each gas supply pipe): 0.01 to 10 slm

After changing the termination with the element X on the surface of the seed layer to the termination with the element Y, the valve 243d is closed and the supply of the element Y-containing gas into the process chamber 201 is stopped. Then, the gaseous substances remaining in the process chamber 201 are removed from the process chamber 201 by the same processing procedure and processing conditions as those of the purging in step A1 (purging). The processing temperature during the purging may be the same as the processing temperature (second temperature) during the supply of the element Y-containing gas.

As the element Y-containing gas, for example, a reducing gas may be used. As the reducing gas, for example, a gas containing hydrogen (H) or deuterium (D) as the element Y may be used. Among them, the gas containing H may be as the reducing gas. That is, the element Y in the element Y-containing gas may include H or D, and may include H.

As the element Y-containing gas, for example, an H-containing gas such as a hydrogen (H₂) gas or the like may be used. Moreover, as the element Y-containing gas, for example, a D-containing gas such as a deuterium (D₂) gas or the like may be used. As the element Y-containing gas, one or more of these gases may be used.

If step A forms the seed layer that includes the surface having a Si—X termination, in this step, the Si—X termination on the surface of the seed layer may be changed to a Si—Y termination. As described above, the element Y may include H or D, and may include H. Therefore, in this step, it may create a state in which a seed layer including a surface having a Si—H termination or a Si-D termination is formed on the surface of the wafer 200. It may create a state in which a seed layer including a surface having Si—H terminations is formed on the surface of the wafer 200.

Further, a processing time in this step may be equal to or longer than a processing time in step C, which will be described below, and may be longer than the processing time in step C. As a result, it is possible to effectively perform the process in this step, to increase the conversion rate of the termination with the element X on the surface of the seed layer to the termination with the element Y, and to prevent the termination with the element X from remaining on the surface of the seed layer. Further, in this case, the processing time in step C described below can be shortened. Therefore, it is possible to improve throughput, i.e., productivity.

### (Step C)

After performing step B, the wafer 200 is set to have a third temperature is higher than the first temperature. As shown in FIG. 4, there is shown an example in which the third temperature is set to be equal to the second temperature. Therefore, in this step, the output of the heater 207 is adjusted so that the processing temperature (third temperature) is maintained at the same temperature as the processing temperature (second temperature) in step B.

Further, a case will now be described in which, as shown in FIG. 4, the inert gas is supplied to the wafer 200 which is set to have the third temperature after step B is performed.

Specifically, the valves 243f to 243h are opened to allow the inert gas to flow into the gas supply pipes 232f to 232h. The flow rate of the inert gas is adjusted by each of the MFCs 241f to 241h. The inert gas is supplied into the process chamber 201 through each of the nozzles 249a to 249c and is exhausted from the exhaust port 231a. At this time, the inert gas is supplied to the wafer 200 from the lateral side of the wafer 200 (inert gas supply).

By supplying the inert gas to the wafer 200 under processing conditions to be described below, it is possible to thermally desorb the element Y which constitutes the termination with the element Y on the surface of the seed layer, and to generate a dangling bond in the surface of the seed layer. In particular, by setting the third temperature to be higher than the first temperature, it is possible to increase a desorption rate of the element Y at the surface of the seed layer and to generate more dangling bonds at the surface of the seed layer. Thus, in this step, a state in which a seed layer including a surface having a dangling bond is formed, that is a state in which a film easily grows during film formation, can be created on the surface of the wafer 200.

A processing conditions when supplying the inert gas in this step is exemplified as follows.
Processing temperature (third temperature): 400 to 520 degrees C., preferably 450 to 500 degrees C.
Processing pressure: 500 to 101325 Pa, preferably 800 to 10133 Pa
Processing time: 0.5 to 2 hours, preferably 0.5 to 1 hour
Inert gas supply flow rate: 1 to 10 slm, preferably 2 to 5 slm

When the Si—X termination on the surface of the seed layer is changed to Si—Y termination in step B, in this step, the Si—Y bond in the Si—Y termination on the surface of the seed layer can be cut to desorb the element Y. This makes it possible to obtain a state in which Si at the surface of the seed layer has a dangling bond. If the surface of the seed layer has a Si—H termination as the Si—Y termination, H can be desorbed in this step to create a state in which Si at the surface of the seed layer has a dangling bond. In this case, in this step, a state in which a seed layer including a surface at which Si has a dangling bond is formed can be created on the surface of the wafer 200.

As described above, FIG. 4 shows an example in which the third temperature is the same as the second temperature. However, the third temperature may be different from the second temperature. By setting the third temperature and the second temperature to be the same, it becomes unnecessary to change the processing temperature between step B and this step, which makes it possible to shorten the time for changing the temperature of the wafer 200 and stabilizing the temperature of the wafer 200. This makes it possible to improve the throughput, i.e., the productivity.

In steps B and C, the second temperature and the third temperature may be set to 400 degrees C. or higher, preferably 450 degrees C. or higher. Moreover, in steps B and C, the second temperature and the third temperature may be set to 520 degrees C. or lower, preferably 500 degrees C. or lower.

If the second temperature is set to be less than 400 degrees C., it may be difficult to change the termination with the element X to the termination with the element Y on the surface of the seed layer. That is, it may be difficult to cause the substitution reaction of the element X with the element Y at the surface of the seed layer. For example, if the surface of the seed layer includes a Si—X termination, it may be difficult to change the Si—X termination on the surface of the seed layer to a Si—Y termination. By setting the second temperature to 400 degrees C. or higher, it is possible to effectively change the termination with the element X to a termination with the element Y on the surface of the seed layer. That is, it is possible to effectively cause the substitution reaction of the element X with the element Y at the surface of the seed layer. For example, when the surface of the seed layer includes a Si—X termination, it is possible to effectively change the Si—X termination on the surface of the seed layer to a Si—Y termination. Further, by setting the second temperature to 450 degrees C. or higher, it is possible to more effectively change the termination with the element X to a termination with the element Y on the surface of the seed layer. That is, it is possible to more effectively cause the substitution reaction of the element X with the element Y at the surface of the seed layer. For example, if the surface of the seed layer includes a Si—X termination, it is possible to more effectively change the Si—X termination on the surface of the seed layer to a Si—Y termination.

If the third temperature is set to be less than 400 degrees C., it may be difficult to desorb the element Y that constitutes the termination with the element Y on the surface of the seed layer. That is, the desorption reaction of the element Y may not occur sufficiently at the surface of the seed layer. For example, if the surface of the seed layer includes a Si—Y termination, it may be difficult to cut the Si—Y bond in the surface of the seed layer to create a state in which Si at the surface of the seed layer has a dangling bond. By setting the third temperature to 400 degrees C. or higher, it is possible to effectively desorb the element Y that constitutes the termination with the element Y on the surface of the seed layer. That is, it is possible to effectively cause the desorption reaction of the element Y at the surface of the seed layer. For example, if the surface of the seed layer includes a Si—Y termination, it is possible to effectively cut the Si—Y bond in the surface of the seed layer and effectively create a state in which Si at the surface of the seed layer has a dangling bond. Further, by setting the third temperature to 450 degrees C. or higher, it is possible to more effectively desorb the element Y that constitutes the termination with the element Y on the surface of the seed layer. That is, it becomes possible to more effectively cause the desorption reaction of the element Y at the surface of the seed layer. For example, if the surface of the seed layer includes a Si—Y termination, it is possible to more effectively cut the Si—Y bond in the surface of the seed layer and more effectively create a state in which Si at the surface of the seed layer has a dangling bond.

Further, if the second and third temperatures are set to exceed 520 degrees C., the main elements constituting the seed layer may be aggregated. As a result, the properties such as surface morphology, surface roughness, and the like of the film formed on the seed layer may be deteriorated. By setting the second temperature and the third temperature to 520 degrees C. or lower, it is possible to effectively suppress aggregation of main elements constituting the seed layer. As a result, it is possible to effectively suppress deterioration of the properties such as surface morphology, surface roughness, and the like of the film formed on the seed layer. By setting the second temperature and the third temperature to 500 degrees C. or lower, it is possible to more effectively suppress aggregation of the main elements constituting the seed layer and more effectively suppress deterioration of the properties such as surface morphology, surface roughness, and the like of the film formed on the seed layer.

As used herein, the terms “surface morphology” and “surface roughness” refer to height differences at the surface of a film within a wafer plane or within an arbitrary target plane. Among them, the surface roughness refers to the degree of height difference at the surface of the film (synonymous with the surface coarseness). A smaller value indicates a smoother surface, and conversely, a larger value indicates a rougher surface. In this specification, the expression “the properties such as surface morphology, surface roughness, and the like being improved” means that the height difference at the surface of a film is reduced and the surface smoothness is improved, and conversely, the expression “the properties such as surface morphology, surface roughness, and the like being deteriorated” means that the height difference at the surface of a film is increased and the surface smoothness is deteriorated.

As can be seen from the above, the second temperature and the third temperature may be set to 400 degrees C. or higher, preferably 450 degrees C. or higher. Further, the second temperature and the third temperature may be set to 520 degrees C. or lower, preferably 500 degrees C. or lower. Moreover, the second temperature and the third temperature may be set to 400 degrees C. or higher and 520 degrees C. or lower, and preferably 450 degrees C. or higher and 500 degrees C. or lower. The second temperature and the third temperature may be the same or different.

In steps B and C, a pressure in the space where the wafer 200 exists, i.e., a pressure inside the process chamber 201 may be set to 500 Pa or more, preferably 800 Pa or more. Further, in steps B and C, the pressure in the space where the wafer 200 exists, i.e., the pressure in the process chamber 201 may be set to 101325 Pa or less, preferably 10133 Pa or less.

If the pressure in the space in which the wafer 200 exists is less than 500 Pa in steps B and C, the main elements constituting the seed layer may be aggregated, and as a result, the properties such as surface morphology, surface roughness, and the like of the film formed on the seed layer may be deteriorated. By setting the pressure in the space where the wafer 200 exists to 500 Pa or more in steps B and C, it is possible to effectively suppress the aggregation of the main elements constituting the seed layer. As a result, it becomes possible to effectively suppress the deterioration of properties such as surface morphology, surface roughness and the like of the film formed on the seed layer. Further, by setting the pressure in the space where the wafer 200 exists to 800 Pa or more in steps B and C, it is possible to more effectively suppress the aggregation of the main elements constituting the seed layer. As a result, it becomes possible to more effectively suppress the deterioration of properties such as surface morphology, surface roughness and the like of the film formed on the seed layer.

If the pressure in the space where the wafer 200 exists exceeds 101325 Pa in Steps B and C, the processing time may be prolonged, and the throughput, i.e., the productivity may decrease. By setting the pressure in the space where the wafer 200 exists to 101325 Pa or less in steps B and C, it is possible to effectively shorten the pressure regulation time and effectively suppress a decrease in the throughput, i.e., the productivity. Further, by setting the pressure in the space where the wafer 200 exists to 10133 Pa or less in steps B and C, it is possible to more effectively shorten the pressure regulation time and more effectively suppress a decrease in the throughput, i.e., the productivity.

As can be seen from the above, the pressure in the space where the wafer 200 exists may be set to 500 Pa or more, more preferably 800 Pa or more in steps B and C. Further, the pressure in the space where the wafer 200 exists may be set to 101325 Pa or less, more preferably 10133 Pa or less in steps B and C. Furthermore, the pressure in the space where the wafer 200 exists may be set to 500 Pa or more and 101325 Pa or less in steps B and C, preferably 800 Pa or more and 10133 Pa or less. The pressure in the space where wafer 200 exists may be the same or different in steps B and C.

### (Temperature Lowering)

After the seed layer formed on the surface of the wafer 200 is processed to have a dangling bond, as shown in FIG. 4, the output of the heater 207 is adjusted to change the processing temperature from the third temperature to a fourth temperature which is set to be equal to or lower than the first temperature, and the fourth temperature may be set to be lower than the first temperature. At this time, the inside of the process chamber 201 is purged according to the same processing procedure and processing conditions as those of the purging in step A1. The purging may be continued until the temperature of the wafer 200 reaches the fourth temperature and stabilizes.

### (Step D)

After the temperature of the wafer 200 reaches the fourth temperature and stabilizes, a film-forming gas is supplied to the wafer 200 which is set to have the fourth temperature. A case will now be described in which a Ge-containing gas is used as the film-forming gas, and the Ge-containing gas is supplied to the wafer 200 together with a dopant gas.

Specifically, the valves 243c and 243e are opened to allow a Ge-containing gas and a dopant gas to flow into the gas supply pipes 232c and 232e, respectively. The flow rates of the Ge-containing gas and the dopant gas are adjusted by the MFC 241c and MFC 241e, and the Ge-containing gas and the dopant gas are supplied into the process chamber 201 through the nozzles 249c and 249b, mixed in the process chamber 201, and exhausted from the exhaust port 231a. At this time, the Ge-containing gas and the dopant gas are supplied to the wafer 200 from the lateral side of the wafer 200 (Ge-containing gas+dopant gas supply). At this time, the valves 243f to 243h may be opened to supply an inert gas into the process chamber 201 through the nozzles 249a to 249c.

In the following example, as shown in FIG. 4, an example is shown in which the fourth temperature is set to be lower than the first temperature. Therefore, in this step, the output of the heater 207 is adjusted to maintain the processing temperature (fourth temperature) lower than the processing temperature (first temperature) in step A (steps A1 and A2).

By supplying a Ge-containing gas as a film-forming gas to the wafer 200 under the processing conditions described below, the Ge-containing gas can be decomposed in the gas phase, and Ge can be adsorbed (deposited) on the seed layer having a dangling bond to form a Ge film. In addition, by supplying the Ge-containing gas to the wafer 200 together with a dopant gas, a dopant-doped Ge film can be formed. Further, under the processing conditions described below, the crystal structure of the Ge film becomes amorphous (non-crystalline).

A processing conditions when supplying the Ge-containing gas in this step is exemplified as follows.
Processing temperature (fourth temperature): 250 to 400 degrees C., preferably 280 to 320 degrees C.
Processing pressure: 30 to 400 Pa
Processing time: 1 to 300 minutes
Ge-containing gas supply flow rate: 0.01 to 5 slm
Dopant gas supply flow rate: 0 to 0.5 slm
Inert gas supply flow rate (for each gas supply pipe): 0.01 to 20 slm

Further, the dopant gas supply flow rate of 0 slm means a case in which no dopant gas is supplied. That is, the supply of the dopant gas can be omitted.

After forming the Ge film on the seed layer, the valves 243c and 243e are closed and the supply of the Ge-containing gas and the dopant gas into the process chamber 201 is stopped. Then, the gaseous substances remaining in the process chamber 201 are removed from the process chamber 201 by the same processing procedure and processing conditions as those of the purging in step A1 (purging).

As the Ge-containing gas, for example, a germanium hydride-based gas (germane-based gas) containing Ge and H may be used. As the Ge-containing gas, for examples, a monogermane (GeH₄) gas, a digermane (Ge₂H₆) gas, a trigermane (Ge₃H₈) gas, or the like may be used. One or more of these gases may be used as the Ge-containing gas.

As the dopant gas, for example, a phosphorus (P)-containing gas, a boron (B)-containing gas, or an arsenic (As)-containing gas may be used. As the dopant gas, a phosphine (PH₃) gas, a diborane (B₂H₆) gas, a trichloroborane (BCl₃) gas, an arsine (AsH₃) gas, or the like may be used. One or more of these gases may be used as the dopant gas.

As described above, FIG. 4 shows the example in which the fourth temperature is set to be lower than the first temperature, but the fourth temperature may be set to be equal to or lower than the first temperature. By setting the fourth temperature to a temperature equal to or lower than the first temperature, preferably a temperature lower than the first temperature, it is possible to reduce the film-forming temperature. In FIG. 4, the second temperature and the third temperature are set to be higher than the first temperature as described above. Therefore, the fourth temperature is set to be the lowest temperature among the first temperature, the second temperature, the third temperature, and four temperature.

Moreover, as described above, the supply of the dopant gas can be omitted in this step. By omitting the supply of the dopant gas, a Ge film not doped with a dopant, i.e., a non-doped Ge film can be formed on the seed layer.

### (Temperature Raising)

After forming the Ge film on the seed layer, purging is performed as described above. At this time, in parallel with the purging, the output of the heater 207 is adjusted to raise the processing temperature from the fourth temperature to a fifth temperature which is higher than the fourth temperature. The purging may be continued until the temperature of the wafer 200 reaches the fifth temperature and stabilizes.

### (Step E)

After the temperature of the wafer 200 reaches the fifth temperature and stabilizes, heat treatment (annealing) is performed on the wafer 200 which is set to have the fifth temperature. In the following example, as shown in FIG. 4, the processing temperature (fifth temperature) in the heat treatment is set to be higher than the fourth temperature. Therefore, in this step, the output of the heater 207 is adjusted to maintain the processing temperature (fifth temperature) higher than the processing temperature in step D (fourth temperature).

This step may be performed while the valves 243f to 243h are opened and the inert gas is supplied into the process chamber 201 through the nozzles 249a to 249c. Further, this step may be performed in a state in which the valves 243f to 243h are closed and the supply of the inert gas into the process chamber 201 is stopped.

The seed layer and the Ge film can be made polycrystalline by heat treatment (annealing) under the processing conditions described below. The seed layer before the heat treatment may be in an amorphous state, in an amorphous (non-crystalline) and polycrystalline (multicrystalline) mixed state, or in a polycrystalline state. In either case, the seed layer can be made polycrystalline, and the Ge film can be made polycrystalline after the seed layer is made polycrystalline. As a result, the Ge film can be made polycrystalline by using the crystal particle (grain) of the seed layer that have been previously made polycrystalline as a nucleus. The heat treatment, i.e., step E, may be omitted if the seed layer and the Ge film are not made polycrystalline.

A processing conditions when performing the heat treatment (annealing) in this step is exemplified as follows.
Processing temperature (fifth temperature): 600 to 1000 degrees C.
Processing pressure: 0.1 to 100000 Pa
Processing time: 1 to 300 minutes
Inert gas supply flow rate (for each gas supply pipe): 0 to 20 slm

### (After-Purging and Atmospheric Pressure Restoration)

After step E is completed, an inert gas as a purge gas is supplied into the process chamber 201 from each of the nozzles 249a to 249c and is exhausted from the exhaust port 231a. As a result, the inside of the process chamber 201 is purged, and the gases, reaction by-products, and the like remaining in the process chamber 201 are removed from the inside of the process chamber 201 (after-purging). Thereafter, the atmosphere in the process chamber 201 is replaced with an inert gas (inert gas replacement), and the pressure in the process chamber 201 is returned to the atmospheric pressure (atmospheric pressure restoration).

### (Boat Unloading and Wafer Discharging)

Thereafter, the seal cap 219 is lowered by the boat elevator 115, and the lower end of the manifold 209 is opened. Then, the processed wafers 200 are unloaded from the lower end of the manifold 209 to the outside of the reaction tube 203 while being supported by the boat 217 (boat unloading). After the boat is unloaded, the shutter 219s is moved and the lower end opening of the manifold 209 is sealed by the shutter 219s via the O-ring 220c (shutter closing). The processed wafers 200 are discharged from the boat 217 after they are unloaded to the outside of the reaction tube 203 (wafer discharging).

### (3) Effects of the Present Embodiment

According to the present embodiment, one or more of the following effects may be obtained.

By performing step B and step C after step A is performed, the surface of the seed layer formed on the surface of the wafer 200 can be modified from the surface terminated with the element X to the surface having a dangling bond. The surface having a dangling bond is a surface on which a film easily grows during film formation, and therefore by supplying the film-forming gas used in step D to the wafer 200 having the seed layer including the surface in such a state, it is possible to suppress uneven film growth. As a result, it is possible to improve the properties such as surface morphology, surface roughness, step coverage, and the like of the film formed on the surface of the seed layer. In addition, it is possible to shorten the incubation time in film formation, and to improve the throughput, i.e., the productivity.

In addition, the above-described surface having a dangling bond in the seed layer is obtained by changing the surface terminated with the element X formed in step A to the surface terminated with the element Y in step B and then desorbing the element Y constituting the termination with the element Y in step C. By doing so, the surface having a dangling bond can be obtained at a lower temperature than, for example, the temperature in the case of desorbing the element X constituting the termination with the element X on the surface of the seed layer. Thus, it is possible to suppress the thermal aggregation of the main elements constituting the seed layer. As a result, it is possible to suppress the deterioration of properties such as surface morphology, surface roughness, and the like of the film formed on the seed layer.

The seed layer including a surface having a Si—X termination may be formed in step A, and the Si—X termination on the surface of the seed layer may be changed to Si—Y termination in step B. Furthermore, in step C, it may cut the Si—Y bond in the Si—Y termination on the surface of the seed layer so that the Si at the surface of the seed layer has a dangling bond. These make it possible to obtain the above effects more efficiently.

The second temperature in step B may be set to be higher than the first temperature in step A, and the third temperature in step C may be set to be higher than the first temperature in step A. This makes it possible to obtain the above effects more efficiently.

The element X in the element X-containing gas, the termination with the element X, and the Si—X termination may include halogen, and may include chlorine. The element Y in the element Y-containing gas, the termination with the element Y, and the S—Y termination may include hydrogen or deuterium. These allow the reactions in steps A, B and C to occur efficiently and effectively, and the above effects can be obtained more remarkably.

In step A, a halosilane-based gas may be supplied to the wafer 200 as the element X-containing gas, and a chlorosilane-based gas may be supplied to the wafer 200 as the element X-containing gas. Moreover, in step A, it may further supply a silicon hydride-based gas to the wafer 200. Furthermore, in step A, it may alternately supply the halosilane-based gas and the silicon hydride-based gas to the wafer 200. In addition, in step B, at least one selected from the group of a hydrogen gas and a deuterium gas may be supplied to the wafer 200 as the element Y-containing gas. These allow the reactions in steps A and B to occur efficiently and effectively, and the above effects can be obtained more remarkably.

In step C, it may supply an inert gas to the wafer 200. This makes it possible to cause the reaction in step C to occur efficiently and effectively, and the above effects can be obtained more remarkably.

### (4) Modifications

The processing sequence in the present embodiment may be modified as in the modifications described below. These modifications can be combined arbitrarily. Unless otherwise specified, the processing procedure and processing conditions in each step of each modification may be the same as the processing procedure and processing conditions in each step of the above-described processing sequence.

### Modification 1

As in the processing sequences indicated below, in step A, the Si-containing gas may not be supplied to the wafer 200. In step A of this modification, by supplying only the element X-containing gas as the reactive gas to the wafer 200 which is set to have the first temperature, a seed layer including a surface terminated with the element X is formed on the surface of the wafer 200. At this time, as in the above-described embodiment, an inert gas may be supplied to the wafer 200. Also in this modification, the same effects as those of the above-described embodiment may be obtained.
Element X-containing gas→element Y-containing gas→inert gas→film-forming gas
Element X-containing gas→element Y-containing gas→inert gas→film-forming gas→heat treatment

### Modification 2

As in the processing sequence indicated below, in step C, the process chamber 201, i.e., the space in which the wafer 200 exists may be evacuated without supplying the inert gas to the wafer 200. In step C of this modification, the temperature of the wafer 200 is set to be the third temperature, and the space in which the wafer 200 exists is evacuated (reduced-pressure-evacuated, vacuum-evacuated, or vacuumized), thereby desorbing the element Y constituting the termination with the element Y on the surface of the seed layer. The processing conditions in this modification may be the same as the processing conditions in step C of the above-described embodiment, except that the supply flow rate of the inert gas is set to 0 slm.
[Element X-containing gas→Si-containing gas]×n→element Y-containing gas→evacuation→film-formation gas
[Element X-containing gas→Si-containing gas]×n→element Y-containing gas→evacuation→film-formation gas→heat treatment
Element X-containing gas→element Y-containing gas→evacuation→film-forming gas
Element X-containing gas→element Y-containing gas→evacuation→film-forming gas→heat treatment

Also in this modification, the same effects as those of the above-described embodiment may be obtained. In addition, as described in the above-described embodiment and this modification, in step C, by performing at least one selected from the group of the supply of the inert gas to the wafer 200 and the evacuation of the space in which the wafer 200 exists, it is possible to efficiently and effectively desorb the element Y that constitutes the termination with the element Y on the surface of the seed layer.

### Modification 3

In step D, the Si-containing gas may be supplied to the wafer 200 which is set to have the fourth temperature. In step D of this modification, instead of the Ge-containing gas used in the above-described embodiment, the Si-containing gas is supplied to the wafer 200 which is set to have the fourth temperature under the processing conditions described below. Thus, the element Y can be desorbed, and a Si film can be formed on the seed layer having a dangling bond. Further, by supplying the Si-containing gas to the wafer 200 together with a dopant gas, a dopant-doped Si film can be formed. In addition, in step D of this modification, the fourth temperature is set to be higher than the first temperature.

A processing conditions when supplying the Si-containing gas in this modification is exemplified as follows.
Processing temperature (fourth temperature): 450 to 650 degrees C.
Processing pressure: 30 to 400 Pa
Processing time: 1 to 300 minutes
Si-containing gas supply flow rate: 0.01 to 5 slm
Dopant gas supply flow rate: 0 to 0.5 slm
Inert gas supply flow rate (for each gas supply pipe): 0.01 to 20 slm

Also in this modification, the same effects as those of the above-described embodiment may be obtained. Moreover, according to this modification, at least one selected from the group of the Si film not doped with a dopant (non-doped Si film) and the Si film doped with a dopant can be formed on the seed layer.

### Modification 4

In step D, a Ge-containing gas and a Si-containing gas may be supplied to the wafer 200 which is set to have the fourth temperature. In step D of this modification, in addition to the Ge-containing gas supplied in the above-described embodiment, the Si-containing gas is supplied to the wafer 200. That is, in step D of this modification, the Si-containing gas and the Ge-containing gas are supplied simultaneously to the wafer 200. Thus, the element Y can be desorbed, and a SiGe film can be formed on the seed layer having a dangling bond. Further, by supplying the Si-containing gas and the Ge-containing gas to the wafer 200 together with a dopant gas, a dopant-doped SiGe film can be formed. In step D of this modification, the fourth temperature may be set to a temperature equal or lower than the first temperature, or may be set to a temperature higher than the first temperature.

A processing conditions when supplying the Si-containing gas and the Ge-containing gas in this modification is exemplified as follows.
Processing temperature (fourth temperature): 280 to 520 degrees C.
Processing pressure: 30 to 400 Pa
Processing time: 1 to 300 minutes
Si-containing gas supply flow rate: 0.01 to 5 slm
Ge-containing gas supply flow rate: 0.01 to 5 slm
Dopant gas supply flow rate: 0 to 0.5 slm
Inert gas supply flow rate (for each gas supply pipe): 0.01 to 20 slm

Also in this modification, the same effects as those of the above-described embodiment may be obtained. Further, according to this modification, at least one selected from the group of the SiGe film not doped with a dopant (non-doped SiGe film) and the SiGe film doped with a dopant can be formed on the seed layer.

As described in the above-described embodiment and modifications 3 and 4, in step D, at least one selected from the group of the Ge-containing gas and the Si-containing gas can be supplied to the wafer 200 as the film-forming gas. Thus, the element Y can be desorbed, and at least one selected from the group of a Ge film, a Si film and a SiGe film, i.e., a film containing at least one selected from the group of Ge and Si, can be formed on the seed layer having a dangling bond. As described above, these films may be films doped with a dopant, or films not doped with a dopant (non-doped films). Also in these cases, the same effects as those of the above-described embodiment may be obtained.

As the Si-containing gas used in modification 3 and modification 4, for example, various silane-based gases, preferably various silicon hydride-based gases exemplified in step A2 of the above-described embodiment may be used. Further, as the dopant gas used in modification 3 and modification 4, for example, various dopant gases exemplified in step D of the above-described embodiment may be used.

### Other Embodiments of the Present Disclosure

The embodiment of the present disclosure has been specifically described above. However, the present disclosure is not limited to the embodiment described above, and may be modified in various ways without departing from the scope of the present disclosure.

For example, in the above-described embodiment, there has been described the example in which a series of steps from step A to step E are performed in the same process chamber 201 (in-situ). However, the present disclosure is not limited to such an embodiment. For example, a series of steps from step A to step D may be performed in the same process chamber, and then step E may be performed in another process chamber (ex-situ). For example, by using a substrate processing system including a plurality of stand-alone type substrate processing apparatuses (a first substrate processing apparatus, a second substrate processing apparatus, a third substrate processing apparatus, or the like), the respective steps may be performed in different process chambers of different substrate processing apparatuses, i.e., in different processing parts. Further, for example, by using a substrate processing system including a cluster-type substrate processing apparatus in which a plurality of process chambers (a first process chamber, a second process chamber, a third process chamber, etc.) are provided around a transfer chamber, the respective steps may be performed in different process chambers of the same substrate processing apparatus, i.e., in different processing parts. Also in these cases, the same effects as those of the above-described embodiment may be obtained.

Further, for example, step F of forming a film (a silicon oxide film, a silicon nitride film, or the like) other than a Ge film, a Si film or a SiGe film may be performed after performing step D and before performing step E. In this case, a series of steps from step A to step E, i.e., a series of steps including step F may be performed in the same process chamber (first process chamber). Further, a series of steps from step A to step D may be performed in the same process chamber (first process chamber), and a series of steps from step F to step E may be performed in another process chamber (second process chamber). Further, a series of steps from step A to step D may be performed in the same process chamber (first process chamber), step F may be performed in another process chamber (second process chamber), and step E may be performed in still another process chamber (third process chamber) or in the first process chamber. Also in these cases, the same effects as those of the above-described embodiment may be obtained.

In the various cases described above, if a series of steps are performed in-situ, the wafer 200 is not exposed to the ambient air during the process, and the wafer 200 can be consistently processed while being kept under vacuum. This makes it possible to perform stable substrate processing. In addition, if some steps are performed ex-situ, the temperature in each process chamber can be set in advance to, for example, the processing temperature in each step or a temperature close to the processing temperature. This makes it possible to shorten the time for temperature regulation, and to improve the throughput, i.e., the productivity.

The recipe used for each process may be is prepared separately according to the processing contents and may be recorded and stored in the memory 121c via an electric communication line or an external memory 123. When starting each process, the CPU 121a may properly select an appropriate recipe from a plurality of recipes recorded and stored in the memory 121c according to the process contents. This makes it possible to form films of various film types, composition ratios, film qualities and film thicknesses with high reproducibility in one substrate processing apparatus. Further, a burden on an operator can be reduced, and each process may be quickly started while avoiding operation errors.

The above-described recipes are not limited to the newly prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. Further, the input/output device 122 included in the existing substrate processing apparatus may be operated to directly change the existing recipes already installed in the substrate processing apparatus.

In the above-described embodiment, a film is formed by using a batch-type substrate processing apparatus configured to process a plurality of substrates at a time. The present disclosure is not limited to the above-described embodiment, but may be suitably applied to, for example, a case where a film is formed using a single-substrate-type substrate processing apparatus for processing one or several substrates at a time. Further, in the above-described embodiment, a film is formed using a substrate processing apparatus having a hot-wall-type process furnace. The present disclosure is not limited to the above-described embodiment, but may also be suitably applied to a case where a film is formed by using a substrate processing apparatus having a cold-wall-type process furnace.

Even when these substrate processing apparatuses are used, each process may be performed under the processing procedures and processing conditions as those of the above-described embodiment and modifications. The same effects as those of the above-described embodiment and modifications may be obtained.

In addition, the above-described embodiment and modifications may be used in combination as appropriate. The processing procedure and processing conditions at this time may be, for example, the same as the processing procedures and processing conditions of the above-described embodiment and modifications.

### EXAMPLES

### Example 1

An evaluation sample 1 of Example 1 was produced by forming a seed layer on a surface of a wafer and forming a Ge film on the seed layer according to a processing sequence similar to the processing sequence shown in FIG. 4. The processing conditions in each step when producing the evaluation sample 1 were set to predetermined conditions falling within the range of the processing conditions in each step of the above-described embodiment. When producing the evaluation sample 1, a Si wafer having a SiO₂ film on the surface thereof was used as the wafer, the chlorosilane-based gas exemplified in the above-described embodiment was used as the element X-containing gas, the silicon hydride-based gas exemplified in the above-described embodiment was used as the Si-containing gas, the H-containing gas exemplified in the above-described embodiment was used as the element Y-containing gas, and the germanium hydride-based gas exemplified in the above-described embodiment was used as the Ge-containing gas. Both the second temperature in step B and the third temperature in step C were set to fall within the range of 500 to 520 degrees C.

### Example 2

An evaluation sample 2 of Example 2 was produced in the same manner as the method for producing the evaluation sample 1 of Example 1, except that both the second temperature in step B and the third temperature in step C are set to fall within the range of 460 to 490 degrees C.

### Example 3

An evaluation sample 3 of Example 3 was produced in the same manner as the method for producing the evaluation sample 1 of Example 1, except that both the second temperature in step B and the third temperature in step C are set to fall within the range of 400 to 440 degrees C.

### Comparative Example 1

An evaluation sample 4 of Comparative Example 1 was produced in the same manner as the method for producing the evaluation sample 1 of Example 1, except that step B and step C are not performed.

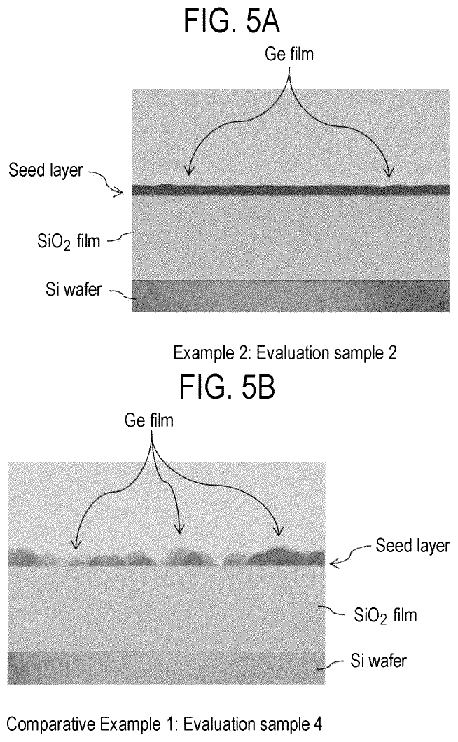

For each produced evaluation sample, the surface portion of the wafer was observed with a transmission electron microscope (TEM) to obtain an image (TEM image). FIG. 5A is a TEM image showing the surface portion of the wafer in the evaluation sample 2 of Example 2, and FIG. 5B is a TEM image showing the surface portion of the wafer in the evaluation sample 4 of Comparative Example 1.

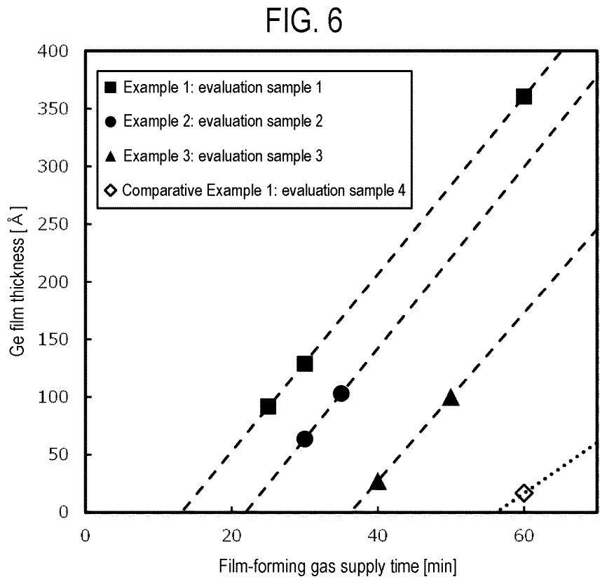

In addition, for each evaluation sample produced, the thickness of the Ge film formed on the seed layer was measured for each supply time of the film-forming gas (Ge-containing gas) in step D, and the time until a film-forming reaction occurs, i.e., the incubation time was evaluated. FIG. 6 shows the evaluation results for the respective evaluation samples. In the graph of FIG. 6, the horizontal axis indicates the supply time (seconds) of the film-forming gas (Ge-containing gas), and the vertical axis indicates the thickness (Å) of the Ge film.

From the comparison of the TEM images of FIG. 5A and FIG. 5B, it was confirmed that, as compared with the evaluation sample 4 of Comparative Example 1, the evaluation sample 2 of Example 2 has a smoother surface of the Ge film, improved surface morphology, improved surface roughness, and excellent step coverage. Further, as shown in FIG. 6, it was confirmed that, as compared with the evaluation sample 4 of Comparative Example 1, the evaluation samples 1 to 3 of Examples 1 to 3 have a significantly shortened incubation time.

According to the present disclosure in some embodiments, it is possible to improve the properties of a film formed on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing substrate, comprising:
(a) forming a layer including a surface terminated with an element X on a surface of a substrate by supplying an element X-containing gas to the substrate which is set to have a first temperature;
(b) changing a surface termination with the element X on the surface of the layer to a surface termination with an element Y by supplying an element Y-containing gas to the substrate which is set to have a second temperature;
(c) desorbing the element Y constituting the surface termination with the element Y on the surface of the layer by setting the substrate to have a third temperature; and
(d) forming a film on the layer from which the element Y is desorbed, by supplying a film-forming gas to the substrate which is set to have a fourth temperature.

2. The method of claim 1, wherein in (a), a surface with a Si—X termination is formed as the surface terminated with the element X, and
wherein in (b), the Si—X termination on the surface of the layer is changed to a Si—Y termination.

3. The method of claim 2, wherein in (c), a Si—Y bond in the Si—Y termination on the surface of the layer is cut, and Si at the surface of the layer is made to have a dangling bond.

4. The method of claim 1, wherein the second temperature is set to be higher than the first temperature, and
wherein the third temperature is set to be higher than the first temperature.

5. The method of claim 4, wherein the fourth temperature is set to be equal to or lower than the first temperature.

6. The method of claim 4, wherein the fourth temperature is set to be higher than the first temperature.

7. The method of claim 1, wherein the element X includes halogen.

8. The method of claim 1, wherein the element X includes chlorine.

9. The method of claim 1, wherein the element Y includes hydrogen or deuterium.

10. The method of claim 7, wherein in (a), a halosilane-based gas is supplied to the substrate as the element X-containing gas.

11. The method of claim 7, wherein in (a), a chlorosilane-based gas is supplied to the substrate as the element X-containing gas.

12. The method of claim 10, wherein in (a), a silicon hydride-based gas is further supplied to the substrate.

13. The method of claim 12, wherein in (a), the halosilane-based gas and the silicon hydride-based gas are alternately supplied to the substrate.

14. The method of claim 9, wherein in (b), at least one selected from the group of a hydrogen gas and a deuterium gas is supplied to the substrate as the element Y-containing gas.

15. The method of claim 1, wherein in (c), at least one selected from the group of supplying an inert gas to the substrate and evacuating a space in which the substrate exists is performed.

16. The method of claim 1, wherein in (d), at least one selected from the group of a germanium-containing gas and a silicon-containing gas is supplied to the substrate as the film-forming gas.

17. The method of claim 1, wherein the second temperature and the third temperature are set to 400 degrees C. or higher and 520 degrees C. or lower.

18. The method of claim 1, wherein a pressure in a space in which the substrate exists is set to 500 Pa or more in (b) and (c).

19. The method of claim 1, wherein a processing time in (b) is equal to or longer than a processing time in (c).

20. A method of manufacturing a semiconductor device, comprising the method of claim 1.

21. A substrate processing apparatus, comprising:
an element X-containing gas supply system configured to supply an element X-containing gas to a substrate;
an element Y-containing gas supply system configured to supply an element Y-containing gas to the substrate;
a film-forming gas supply system configured to supply a film-forming gas to the substrate;
a temperature regulator configured to regulate a temperature of the substrate; and
a controller configured to be capable of controlling the element X-containing gas supply system, the element Y-containing gas supply system, the film-forming gas supply system, and the temperature regulator to perform a process including:
(a) forming a layer including a surface terminated with an element X on a surface of the substrate by supplying the element X-containing gas to the substrate which is set to have a first temperature,
(b) changing a surface termination with the element X on the surface of the layer to a surface termination with an element Y by supplying the element Y-containing gas to the substrate which is set to have a second temperature,
(c) desorbing the element Y constituting the surface termination with the element Y on the surface of the layer by setting the substrate to have a third temperature, and
(d) forming a film on the layer from which the element Y is desorbed, by supplying the film-forming gas to the substrate which is set to have a fourth temperature.

22. A non-transitory computer-readable recording medium storing a program that causes, by a computer, a substrate processing apparatus to perform a process comprising:
(a) forming a layer including a surface terminated with an element X on a surface of a substrate by supplying an element X-containing gas to the substrate which is set to have a first temperature;
(b) changing a surface termination with the element X on the surface of the layer to a surface termination with an element Y by supplying an element Y-containing gas to the substrate which is set to have a second temperature;
(c) desorbing the element Y constituting the surface termination with the element Y on the surface of the layer by setting the substrate to have a third temperature; and
(d) forming a film on the layer from which the element Y is desorbed, by supplying a film-forming gas to the substrate which is set to have a fourth temperature.
